(19) United States
(12) Patent Application Publication
(10) Pub. No.: US 2026/0183972 A1
(43) Pub. Date: Jul. 2, 2026

(54) APPARATUS AND METHOD FOR CONVEYING SUBSTRATE

(71) Applicant: SEMES CO., LTD., Cheonan-si (KR)

(72) Inventors: Hyun Jun KIM, Pyeongtaek-si (KR); Jun Ho YOU, Cheonan-si (KR)

(21) Appl. No.: 19/401,303

(22) Filed: Nov. 25, 2025

(30) Foreign Application Priority Data
Dec. 27, 2024 (KR) 10-2024-0198219

(51) Int. Cl. B25J 15/06

(52) U.S. Cl. CPC B25J 15/0616

(57) ABSTRACT

A substrate conveyance apparatus includes a hand supporting a substrate, the hand having a plurality of holes formed in a surface thereof, an adsorption unit vacuum-adsorbing the substrate placed on the hand through the plurality of holes, a movement unit connected to one end of the hand, the movement unit moving the hand in a vertical direction, and a control unit controlling the hand, the adsorption unit, and the movement unit. The control unit controls, based on a result of inspection of an adsorption state of the substrate using the adsorption unit, movement of the hand in the vertical direction using the movement unit.

### CROSS-REFERENCE TO RELATED APPLICATION(S)

This application claims benefit of priority to Korean Patent Application No. 10-2024-0198219 filed on Dec. 27, 2024 in the Korean Intellectual Property Office, the disclosure of which is incorporated herein by reference in its entirety.

### BACKGROUND

### 1. Field

The present disclosure relates to a method and apparatus for conveying a substrate.

### 2. Description of Related Art

When a semiconductor is manufactured, several processes may be required to form a desired pattern on a substrate. Respective processes may include a plurality of processing operations, and may be performed by different processing apparatuses.

Accordingly, a conveyance robot may convey a substrate to each apparatus. In general, the conveyance robot may be provided with a hand supporting a substrate, and the substrate may be transferred in a state of being mounted on the hand.

A vacuum adsorption module may be installed in the hand of the conveyance robot to prevent the substrate from being separated therefrom during a transfer process.

FIGS. 1A and 1B illustrate operations of a substrate conveyance apparatus 10 according to the related art. As illustrated in FIGS. 1A and 1B, the substrate conveyance apparatus 10 may include a hand 110 and a hand support member 120.

The hand 110 may fix a substrate W to an upper surface thereof by vacuum adsorption of the substrate W. The hand support member 120 may be connected to one end of the hand 110 to support the hand 110.

When warpage occurs in the substrate W raised on the hand 110 as illustrated in FIG. 1A, vacuum adsorption of the hand 110 may not be properly performed due to a gap present between the hand 110 and the substrate W.

A substrate conveyance apparatus 10 according to the related art may properly vacuum-adsorb the substrate W and perform transfer of the substrate W only when warpage of the substrate W does not occur, as illustrated in FIG. 1B.

### SUMMARY

An aspect of the present disclosure is to provide a substrate conveyance apparatus and method capable of preventing separation or damage of a substrate through inspection of an adsorption state of the substrate mounted on a conveyance hand.

Another aspect of the present disclosure is to provide a substrate conveyance apparatus and method capable of controlling movement of a conveyance hand without generating an alarm in the case that the conveyance hand fails in adsorption of a substrate.

Another aspect of the present disclosure is to provide a substrate conveyance apparatus and method capable of allowing gripping of a substrate to be properly performed by moving the substrate to a cooling plate and lowering and maintaining a conveyance hand in a standby state when adsorption of the substrate fails due to warpage of the substrate.

The aspects of the present disclosure are not limited to those set forth herein. A person having ordinary skill in the art to which the present disclosure pertains may have no difficulty in understanding additional aspects of the present disclosure from the overall contents of the present specification.

According to an aspect of the present disclosure, there is provided a substrate conveyance apparatus including a hand supporting a substrate, the hand having a plurality of holes formed in a surface thereof, an adsorption unit vacuum-adsorbing the substrate placed on the hand through the plurality of holes, a movement unit connected to one end of the hand, the movement unit moving the hand in a vertical direction, and a control unit controlling the hand, the adsorption unit, and the movement unit. The control unit may control, based on a result of inspection of an adsorption state of the substrate using the adsorption unit, movement of the hand in the vertical direction using the movement unit.

According to another aspect of the present disclosure, there is provided a substrate conveyance method including mounting a substrate on a conveyance hand, vacuum-adsorbing the substrate through a plurality of holes formed in a surface of the conveyance hand, measuring internal pressure of a vacuum passage communicating with the plurality of holes, determining, based on the internal pressure of the vacuum passage, an adsorption state of the substrate, and controlling, based on the adsorption state of the substrate, movement of the conveyance hand in a vertical direction.

According to another aspect of the present disclosure, there is provided a substrate conveyance apparatus including a hand supporting a substrate, the hand having a plurality of holes formed in a surface thereof, an adsorption unit including a plurality of vacuum pads, vacuum-adsorbing the substrate placed on the hand, and a vacuum passage, a movement unit connected to one end of the hand, the movement unit moving the hand in a horizontal direction or a vertical direction, a cooling plate cooling the substrate, and a control unit controlling the hand, the adsorption unit, and the movement unit. The control unit may determine, based on internal pressure of the vacuum passage, an adsorption state of the substrate, and may control, based on the adsorption state of the substrate, movement of the hand in the vertical direction.

According to example embodiments of the present disclosure, a substrate conveyance apparatus and method may prevent separation or damage of a substrate through inspection of an adsorption state of the substrate mounted on a conveyance hand.

According to example embodiments of the present disclosure, a substrate conveyance apparatus and method may control movement of a conveyance hand without generating an alarm in the case that the conveyance hand fails in adsorption of a substrate.

According to example embodiments of the present disclosure, a substrate conveyance apparatus and method may allow gripping of a substrate to be properly performed by moving the substrate to a cooling plate and lowering and maintaining a conveyance hand in a standby state when adsorption of the substrate fails due to warpage of the substrate.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A illustrates an operation of a substrate conveyance apparatus according to the related art;

FIG. 1B illustrates an operation of a substrate conveyance apparatus according to the related art;

FIG. 2 is a top view of a substrate conveyance apparatus according to an example embodiment of the present disclosure;

FIG. 3 is a top view of a substrate conveyance apparatus according to another embodiment of the present disclosure;

FIG. 4 illustrates an operation of a substrate conveyance apparatus according to an example embodiment of the present disclosure;

FIG. 5 illustrates an operation of a substrate conveyance apparatus according to an example embodiment of the present disclosure;

FIG. 6 illustrates an operation of a substrate conveyance apparatus according to an example embodiment of the present disclosure;

FIG. 7 illustrates an operation of a substrate conveyance apparatus according to an example embodiment of the present disclosure;

FIG. 8 illustrates an operation of a substrate conveyance apparatus according to an example embodiment of the present disclosure;

FIG. 9 is a top view of a substrate conveyance apparatus according to another embodiment of the present disclosure;

FIG. 10 is a top view of a substrate conveyance apparatus according to another embodiment of the present disclosure; and

FIG. 11 is a flowchart of a substrate conveyance method according to an example embodiment of the present disclosure.

### DETAILED DESCRIPTION

Hereinafter, preferred example embodiments are described in detail with reference to the accompanying drawings such that those skilled in the art can readily practice the present disclosure. However, the example embodiments of the present disclosure may be modified into various other forms, and the scope of the present disclosure is not limited to the example embodiments described below.

In addition, example embodiments of the present disclosure are provided to further describe the present disclosure to those skilled in the art.

In the drawings, shapes, sizes, and the like of elements may be exaggerated or reduced for clearer illustration.

In describing the example embodiments of the present disclosure, when it is determined that a detailed description of a known technology related to the present disclosure may unnecessarily obscure the gist of the present disclosure, the detailed description thereof will be omitted. In addition, terms to be described below are terms defined in consideration of functions in the present disclosure, which may vary depending on intention or custom of a user or operator. Therefore, the definition of these terms should be made based on the contents throughout the present specification. The terminology used herein is for the purpose of describing particular example embodiments only and is not to be limiting of the example embodiments. As used herein, the singular forms “a,” “an,” and “the” are intended to include the plural forms as well, unless the context clearly indicates otherwise.

In addition, in the present specification, terms such as “upper,” “upper portion,” “upper surface,” “lower,” “lower portion,” “lower surface,” and “side surface” are based on the drawings, may vary depending on a direction in which an element or component is actually disposed.

When it is mentioned that one component is “connected” or “accessed” to another component, it may be understood that the one component is directly connected or accessed to another component or that still other component is interposed between the two components. In addition, it should be noted that if it is described in the specification that one component is “directly connected” or “directly joined” to another component, still other component may not be present therebetween. In addition, it will be understood that “comprises” and/or “comprising” specify the presence of stated features, integers, steps, operations, elements, components or a combination thereof, but do not preclude the presence or addition of one or more other features, integers, steps, operations, elements, components, and/or groups thereof.

Hereinafter, the present disclosure will be described in detail through each example embodiment or example. It should be noted that each example embodiment or example described herein is not limited to a single example embodiment or example, and combinations with other example embodiments or examples are also possible. Accordingly, citation of claims in the claims section correspond to only one example of an example embodiment, and the technical concept of the present disclosure should not be construed as being limited to combinations with the cited claims. Combinations with various claims are also within the scope of the technical concept of the present disclosure.

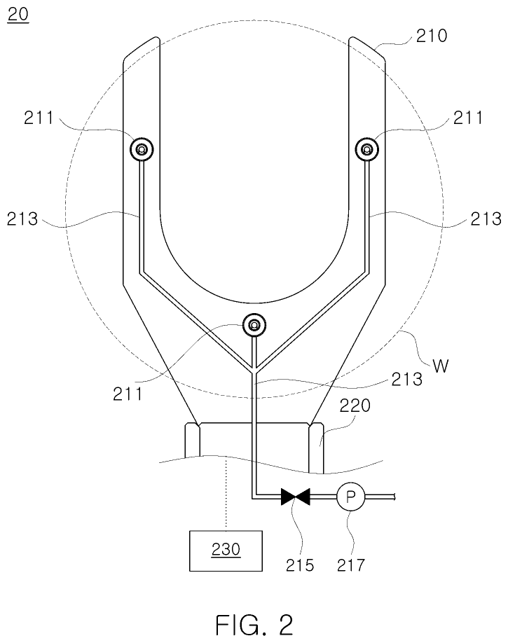

FIG. 2 is a top view of a substrate conveyance apparatus according to an example embodiment of the present disclosure.

As illustrated in FIG. 2, a substrate conveyance apparatus 20 may include a hand 210, adsorption units 211, 213, 215, and 217, a movement unit 220, and a control unit 230.

The hand 210 may support at least a portion of a substrate W. The hand 210 may provide a surface on which a substrate W is mounted.

A plurality of holes may be formed in a surface of the hand 210. FIG. 2 illustrates a case in which three holes are formed on the surface of the hand 210.

The adsorption units 211, 213, 215, and 217 may vacuum-adsorb the substrate W through the plurality of holes formed in the hand 210.

The adsorption units 211, 213, 215, and 217 may include a plurality of vacuum pads 211, a vacuum passage 213, a pressure regulating member 215, and a pressure gauge 217.

The plurality of vacuum pads 211 may be disposed in the plurality of holes of the hand 210. The plurality of vacuum pads 211 may adsorb the substrate W.

The plurality of vacuum pads 211 may include, for example, an annular elastic members

The vacuum passage 213 may be disposed in the hand 210. The vacuum passage 213 may communicate with the plurality of holes of the hand 210.

The pressure regulating member 215 may be installed in the vacuum passage 213. The pressure regulating member 215 may generate vacuum adsorption force by adjusting internal pressure of the vacuum passage 213.

The pressure gauge 217 may be installed in the vacuum passage 213. The pressure gauge 217 may measure pressure the internal pressure of the vacuum passage 213.

FIG. 2 illustrates a case in which the vacuum passage 213 extends from the plurality of holes and merges into a single passage. The pressure regulating member 215 and the pressure gauge 217 may be installed in the merged portion of the vacuum passage 213.

The movement unit 220 may be connected to one end of the hand 210, and may support the hand 210. The movement unit 220 may move the hand 210 in a horizontal direction or a vertical direction.

The control unit 230 may control the hand 210, the adsorption units 211, 213, 215, and 217, and the movement unit 220.

The control unit 230 may perform inspection of an adsorption state of the substrate W using the adsorption units 211, 213, 215, and 217.

The control unit 230 may reduce the internal pressure of the vacuum passage 213 using the pressure regulating member 215, and may apply vacuum adsorption force to a lower surface of the substrate W through the plurality of holes.

The control unit 230 may perform, based on a measured value of the pressure gauge 217, inspection of the adsorption state of the substrate W after generating the vacuum adsorption force.

When warpage occurs in the substrate W, adsorption of the substrate W may not be properly performed due to a gap present between the substrate W and the hand 210. When the measured value of the pressure gauge 217 is less than a preset reference pressure value, the control unit 230 may determine an adsorption state of the substrate W, as an abnormal state.

Conversely, when the measured value of the pressure gauge 217 is greater than the preset reference pressure value, the control unit 230 may determine the adsorption state of the substrate W, as a normal state.

The control unit 230 may control the movement unit 220, based on a result of performing inspection of the adsorption state of the substrate W. The control unit 230 may control, based on the adsorption state of the substrate W, movement of the hand 210 in the vertical direction using the movement unit 220.

For example, the control unit 230 may lower the hand 210 using the movement unit 220 when the adsorption state of the substrate W is determined as the abnormal state.

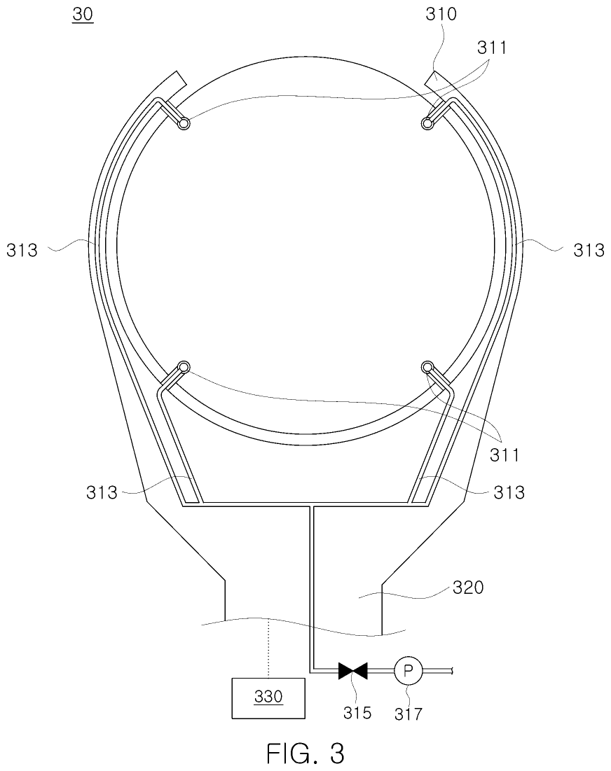

FIG. 3 is a top view of a substrate conveyance apparatus according to another example embodiment of the present disclosure. A substrate conveyance apparatus 30 may include a hand 310, adsorption units 311, 313, 315, and 317, a movement unit 320, and a control unit 330.

The substrate conveyance apparatus 30 illustrated in FIG. 3 may be almost the same as the substrate conveyance apparatus 20 according to the example embodiment illustrated in FIG. 2, and detailed descriptions of the same configurations will be omitted.

The substrate conveyance apparatus 30 may be different from the substrate conveyance apparatus 20 only in that the substrate conveyance apparatus 30 has four holes formed in the hand 310, four vacuum pads 311 disposed in the four holes, and a vacuum passage 313 communicating with the four holes.

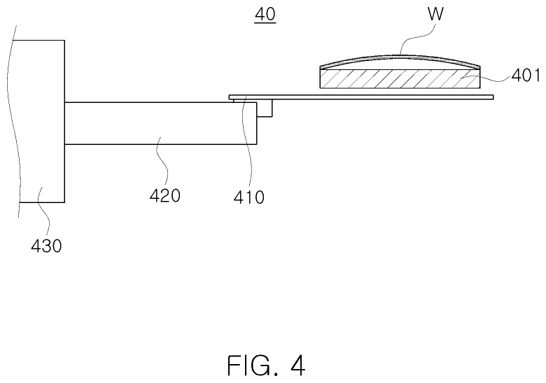

FIGS. 4 to 8 illustrate operations of a substrate conveyance apparatus according to an example embodiment of the present disclosure. Operations of a substrate conveyance apparatus 40 illustrated in FIGS. 4 to 8 may be implemented using a substrate conveyance apparatus, such as the substrate conveyance apparatus illustrated in FIG. 2 or FIG. 3.

The substrate conveyance apparatus 40 may include a hand 410, a movement unit 420, a control unit 430, and a cooling plate 401.

The hand 410 may have a plurality of holes. As described with reference to FIGS. 2 and 3, the hand 410 may include an adsorption unit generating vacuum adsorption force on a lower surface of the substrate W through the plurality of holes.

The hand 410 may support a substrate W. For example, the hand 410 may grip the substrate W from the cooling plate 401.

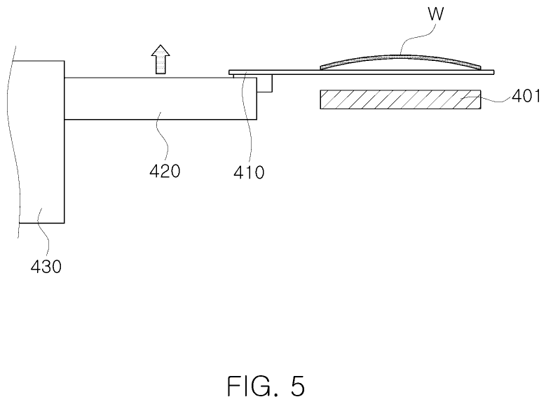

As illustrated in FIG. 5, the control unit 430 may raise the hand 410 to a position higher than the cooling plate 401 using the movement unit 420. The control unit 430 may perform inspection of an adsorption state of the substrate W, in a state in which the hand 410 is raised to the position higher than the cooling plate 401.

Inspection of the adsorption state of the substrate W may be performed based on a measured value of a pressure gauge after internal pressure of the vacuum passage is reduced, as described with reference to FIG. 2.

The control unit 430 may determine the adsorption state of the substrate W, as an abnormal state when the measured value of the pressure gauge is less than a preset reference pressure value. When the adsorption state of the substrate W is determined as the abnormal state, the control unit 430 may maintain the hand 410 in a standby state for a preset standby time.

The control unit 430 may re-perform inspection of the adsorption state of the substrate W after maintaining the hand 410 in a standby state for the preset standby time.

The control unit 430 may determine the adsorption state of the substrate W, as a normal state when the measured value of the pressure gauge is greater than the preset reference pressure value. When the adsorption state of the substrate W is determined as the normal state, the control unit 430 may transfer the substrate W, in a state of adsorbing the substrate W.

When the adsorption state of the substrate W is determined as the abnormal state as a result of re-performing inspection of the adsorption state of the substrate W, the control unit 430 may place down the substrate W from the hand 410 onto the cooling plate 401.

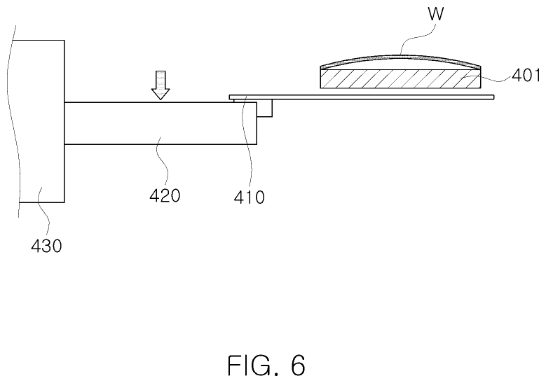

As illustrated in FIG. 6, the control unit 430 may lower the hand 410 to a position lower than the cooling plate 401 using the movement unit 420 after placing down the substrate W onto the cooling plate 401.

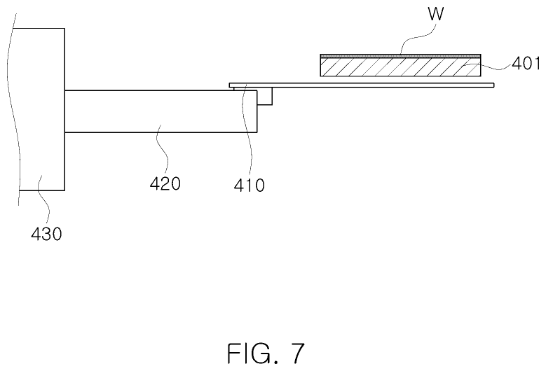

As illustrated in FIG. 7, the control unit 430 may maintain the hand 410 in a standby state such that the substrate W is cooled for a preset cooling time. The substrate W may be cooled on the cooling plate 401, thereby reducing warpage.

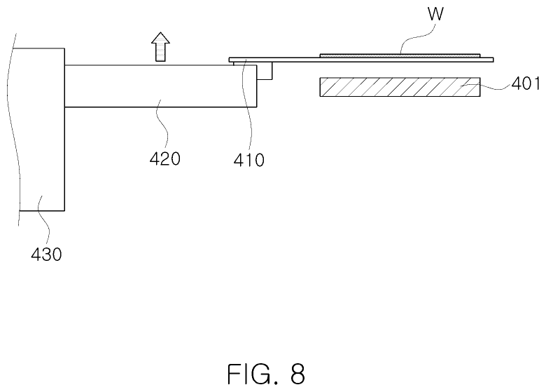

Subsequently, as illustrated in FIG. 8, the control unit 430 may raise the hand 410 using the movement unit 420 after the preset cooling time. The control unit 430 may mount the substrate W from the cooling plate 401 onto the hand 410.

According to the present disclosure, a substrate may be effectively prevented from being separated from a hand or being damaged during transfer through inspection of an adsorption state of the substrate.

In addition, the present disclosure may provide a substrate conveyance apparatus and method capable of controlling movement of a conveyance hand without generating an alarm in the case that the conveyance hand fails in adsorption of a substrate.

In addition, according to the present disclosure, when adsorption of a substrate fails due to warpage of the substrate, the substrate may be moved to a cooling plate and a conveyance hand may be lowered and maintained in a standby state, such that gripping of the substrate may be properly performed after warpage of the substrate is removed.

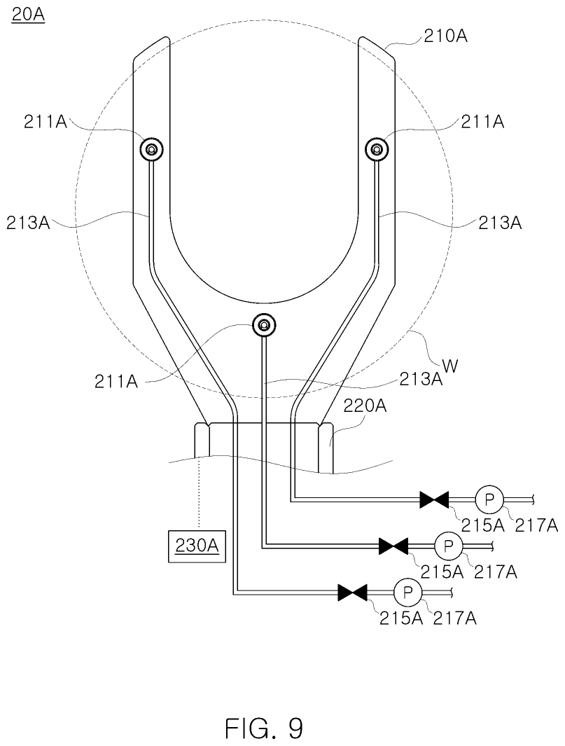

FIG. 9 illustrates a substrate conveyance apparatus according to another example embodiment of the present disclosure. A substrate conveyance apparatus 20A may include a hand 210A, adsorption units 211A, 213A, 215A, and 217A, a movement unit 220A, and a control unit 230A.

The substrate conveyance apparatus 20A may be almost the same as the substrate conveyance apparatus 20 according to the example embodiment illustrated in FIG. 2, and detailed descriptions of the same configurations will be omitted.

As compared to the substrate conveyance apparatus 20 according to the example embodiment illustrated in FIG. 2, the substrate conveyance apparatus 20A may include a plurality of vacuum passages 213A extending from a plurality of holes formed in the hand 210A.

The substrate conveyance apparatus 20A may include a plurality of pressure regulating members 215A and a plurality of pressure gauges 217A, respectively installed in the plurality of vacuum passages 213A.

The plurality of pressure regulating members 215A may individually regulate internal pressure of the plurality of vacuum passages 213A.

The plurality of pressure gauges 217A may individually measure internal pressure of the plurality of vacuum passages 213A.

The substrate conveyance apparatus 20A may derive a degree of warpage of each of regions of the substrate W, using measured values of the plurality of pressure gauges 217A. The substrate conveyance apparatus 20A may estimate a shape of the substrate W, using the measured values of the plurality of pressure gauges 217A.

The substrate conveyance apparatus 20A may increase or decrease standby time of the hand 210A or cooling time of the substrate W, based on the measured values of the plurality of pressure gauges 217A.

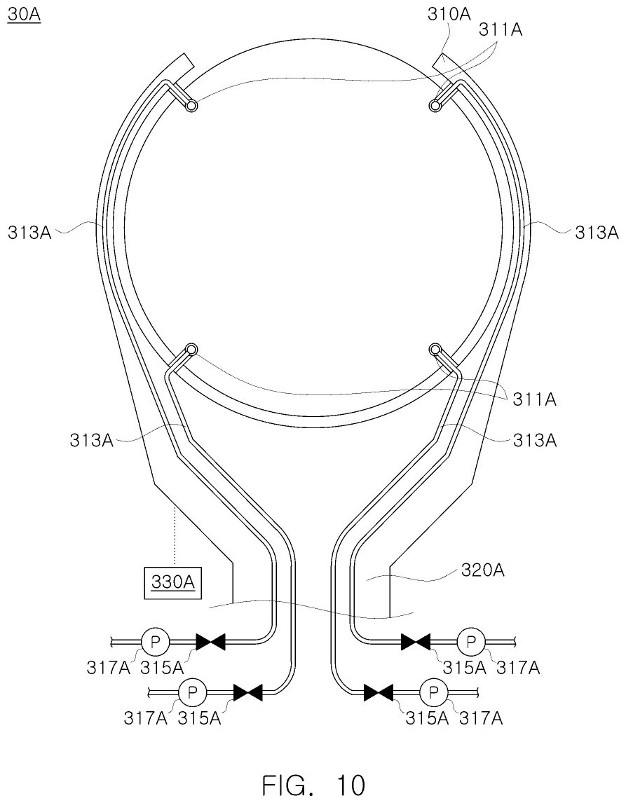

FIG. 10 illustrates a substrate conveyance apparatus according to another example embodiment of the present disclosure. A substrate conveyance apparatus 30A may include a hand 310A, adsorption units 311A, 313A, 315A, and 317A, a movement unit 320A, and a control unit 330A.

The substrate conveyance apparatus 30A may be almost the same as the substrate conveyance apparatus 20 according to the example embodiment illustrated in FIG. 2, and detailed descriptions of the same configurations will be omitted.

In a similar manner to the substrate conveyance apparatus 20A according to the example embodiment illustrated in FIG. 9, the substrate conveyance apparatus 30A may include a plurality of vacuum passages 313A extending from a plurality of holes formed in the hand 310A.

The substrate conveyance apparatus 30A may include a plurality of pressure regulating members 315A and a plurality of pressure gauges 317A, respectively installed in the plurality of vacuum passages 313A.

The plurality of pressure regulating members 315A may individually regulate internal pressure of the plurality of vacuum passages 313A.

The plurality of pressure gauges 317A may individually measure internal pressure of the plurality of vacuum passages 313A.

The substrate conveyance apparatus 30A may derive a degree of warpage of each of regions of the substrate W, using measured values of the plurality of pressure gauges 317A. The substrate conveyance apparatus 30A may estimate a shape of the substrate W, using the measured values of the plurality of pressure gauges 317A.

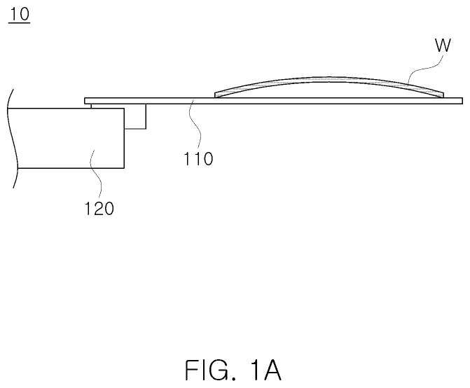

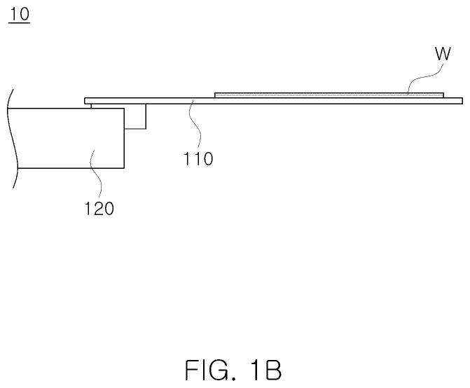

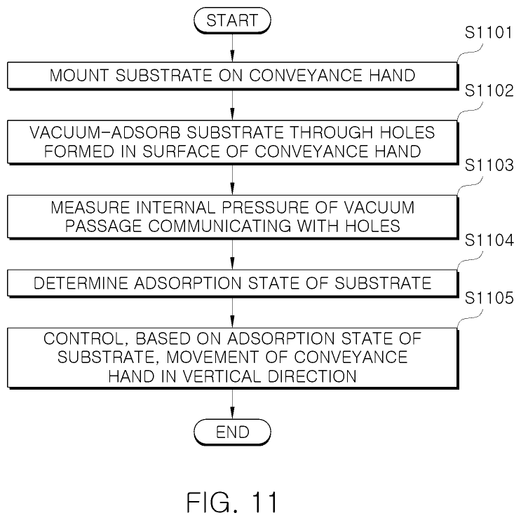

FIG. 11 is a flowchart of a substrate conveyance method according to an example embodiment of the present disclosure. The substrate conveyance method illustrated in FIG. 11 may be performed using the substrate conveyance apparatuses described with reference to FIGS. 1 to 10.

Referring to FIG. 11, the substrate conveyance method may include an operation (S1101) of mounting a substrate on a conveyance hand, an operation (S1102) of vacuum-adsorbing the substrate through a plurality of holes formed in a surface of the conveyance hand, an operation (S1103) of measuring internal pressure of a vacuum passage communicating with the plurality of holes, an operation (S1104) of determining an adsorption state of the substrate, and an operation (S1105) of controlling, based on the adsorption state of the substrate, movement of the conveyance hand in a vertical direction.

The operation (S1103) of measuring internal pressure of the vacuum passage may be performed using a pressure gauge installed in the vacuum passage.

In an example embodiment, when the vacuum passage extends from the plurality of holes and is merged into a single passage, the pressure gauge may be installed in the merged single passage.

In another example embodiment, when the vacuum passage includes a plurality of passages extending from the plurality of holes, the pressure gauge may be installed in each of the plurality of passages.

The operation (S1104) of determining the adsorption state of the substrate may determine the adsorption state of the substrate, based on the internal pressure of the vacuum passage.

For example, when a measured value of the pressure gauge is less than a preset reference pressure value, the adsorption state of the substrate may be determined as an abnormal state.

The substrate conveyance method may further include an operation of maintaining the conveyance hand for a preset standby time, and then re-determining the adsorption state of the substrate when the adsorption state of the substrate is determined as the abnormal state.

Conversely, when the measured value of the pressure gauge is greater than the preset reference pressure value, the adsorption state of the substrate may be determined as a normal state.

In the substrate conveyance method, the substrate may be transferred in a state in which the substrate is adsorbed when the adsorption state of the substrate is determined as the normal state.

The substrate conveyance method may further include an operation of placing down the substrate from the conveyance hand onto a cooling plate when the adsorption state of the substrate is determined as the abnormal state as a result of re-determining the adsorption state, an operation of lowering the conveyance hand to a position lower than the cooling plate, an operation of raising the conveyance hand after a preset cooling time, and an operation of retrieving the substrate from the cooling plate and mounting the substrate on the conveyance hand.

In some example embodiments provided in the present application, it should be understood that the device and method described herein may be implemented in other manners. For example, the above-described device example embodiment is merely an example. For example, division of the units is merely division of logical functions, and may be other division in actual implementation. For example, a plurality of units or components may be combined or integrated into another system, or some components may be ignored or may not be performed. In addition, mutual couplings, direct couplings, or communication connections displayed or discussed may be indirect couplings or communication connections implemented using some interfaces, devices or units, and may be implemented in electrical, mechanical, or other form.

The units described above as separate parts may be physically separated from each other, and parts displayed as units may be or may not be physical units. Thus, the parts may be disposed in one position, or may be distributed on a plurality of network units. Some or all of the units may be selected based on actual requirements to achieve aspects of the present disclosure.

That is, functional units in the example embodiments of the present disclosure may be integrated into one processing unit, or each of the units may be present solely, or two or more units are integrated into one unit.

Example embodiments of the present disclosure may include a program for performing the methods described herein on a computer, and a computer-readable recording medium including the program. The computer-readable recording medium may include, alone or in combination with program instructions, local data files, local data structures, and the like. The medium may be those specially designed and constructed for the purposes of the example embodiments, or may be of the well-known kind and available to those having skill in the computer software arts. Examples of the computer-readable medium include magnetic media such as hard disks, floppy disks, and magnetic tape, optical media such as CD ROM discs and DVDs, magneto-optical media such as optical discs, and hardware devices that are specially configured to store and perform program instructions, such as read-only memory (ROM), random access memory (RAM), flash memory, and the like. Examples of the program may include both a machine code, such as a code produced by a compiler, and a higher-level code that may be executed by the computer using an interpreter.

While example embodiments have been illustrated and described above, it will be apparent to those skilled in the art that modifications and variations could be made without departing from the scope of the present disclosure as defined by the appended claims. Therefore, the scope of the present disclosure should not be limited to the described example embodiments, and should be defined not only by the following claims but also by equivalents thereof.

What is claimed is:

1. A substrate conveyance apparatus comprising:
a hand supporting a substrate, the hand having a plurality of holes formed in a surface thereof;
an adsorption unit vacuum-adsorbing the substrate placed on the hand through the plurality of holes;
a movement unit connected to one end of the hand, the movement unit moving the hand in a vertical direction; and
a control unit controlling the hand, the adsorption unit, and the movement unit,
wherein the control unit controls, based on a result of inspection of an adsorption state of the substrate using the adsorption unit, movement of the hand in the vertical direction using the movement unit.

2. The substrate conveyance apparatus of claim 1, wherein the adsorption unit includes:
a plurality of vacuum pads disposed in the plurality of holes, the plurality of vacuum pads adsorbing the substrate;
a vacuum passage disposed in the hand, the vacuum passage communicating with the plurality of holes; and
a pressure gauge installed in the vacuum passage, the pressure gauge measuring internal pressure of the vacuum passage.

3. The substrate conveyance apparatus of claim 2, wherein the vacuum passage extends from the plurality of holes and is merged into a single passage, and the pressure gauge is installed in the merged single passage.

4. The substrate conveyance apparatus of claim 3, wherein
the adsorption unit further includes a pressure regulating member installed in the vacuum passage, the pressure regulating member adjusting the internal pressure of the vacuum passage, and
the control unit reduces the internal pressure of the vacuum passage using the pressure regulating member, and then performs, based on a measured value of the pressure gauge, inspection of an adsorption state of the substrate.

5. The substrate conveyance apparatus of claim 4, further comprising:
a cooling plate supporting the substrate, the cooling plate cooling the substrate,
wherein the control unit performs inspection of the adsorption state of the substrate in a state of raising the hand to a position higher than the cooling plate using the movement unit.

6. The substrate conveyance apparatus of claim 5, wherein
the control unit determines the adsorption state of the substrate as an abnormal state when the measured value of the pressure gauge is less than a preset reference pressure value, and
when the adsorption state of the substrate is determined as the abnormal state, the control unit maintains the hand in a standby state for a preset standby time and then re-performs inspection of the adsorption state of the substrate.

7. The substrate conveyance apparatus of claim 6, wherein, when the adsorption state of the substrate is determined as the abnormal state based on a result of re-performing inspection of the adsorption state of the substrate, the control unit places down the substrate from the hand onto the cooling plate, and lowers the hand to a position lower than the cooling plate using the movement unit.

8. The substrate conveyance apparatus of claim 7, wherein, after a preset cooling time, the control unit raises the hand using the movement unit, and mounts the substrate on the hand.

9. The substrate conveyance apparatus of claim 2, wherein the vacuum passage includes a plurality of vacuum passages extending from the plurality of holes, and the pressure gauge is installed in each of the plurality of vacuum passages.

10. The substrate conveyance apparatus of claim 9, wherein the adsorption unit further includes a plurality of pressure regulating members respectively installed in the plurality of vacuum passages, the plurality of pressure regulating members individually adjusting internal pressure of the plurality of vacuum passages.

11. A substrate conveyance method comprising:
mounting a substrate on a conveyance hand;
vacuum-adsorbing the substrate through a plurality of holes formed in a surface of the conveyance hand;
measuring internal pressure of a vacuum passage communicating with the plurality of holes;
determining, based on the internal pressure of the vacuum passage, an adsorption state of the substrate; and
controlling, based on the adsorption state of the substrate, movement of the conveyance hand in a vertical direction.

12. The substrate conveyance method of claim 11, wherein
the vacuum passage extends from the plurality of holes and is merged into a single passage, and
the measuring the internal pressure of the vacuum passage includes measuring the internal pressure of the vacuum passage using a pressure gauge installed in the merged single passage.

13. The substrate conveyance method of claim 12, wherein the determining the adsorption state of the substrate includes determining the adsorption state of the substrate as an abnormal state when a measured value of the pressure gauge is less than a preset reference pressure value, and determining the adsorption state of the substrate as a normal state when the measured value of the pressure gauge is greater than the preset reference pressure value.

14. The substrate conveyance method of claim 13, further comprising:
maintaining the conveyance hand in a standby state for a preset standby time, and then re-determining the adsorption state of the substrate, when the adsorption state of the substrate is determined as the abnormal state.

15. The substrate conveyance method of claim 14, further comprising:
placing down the substrate from the conveyance hand onto a cooling plate cooling the substrate, when the adsorption state of the substrate is determined as the abnormal state as a result of re-determining the adsorption state of the state; and
lowering the conveyance hand to a position lower than the cooling plate.

16. The substrate conveyance method of claim 15, further comprising:
raising the conveyance hand after a preset cooling time; and
retrieving the substrate from the cooling plate and mounting the substrate on the conveyance hand.

17. The substrate conveyance method of claim 11, wherein
the vacuum passage includes a plurality of vacuum passages extending from the plurality of holes, and
the measuring the internal pressure of the vacuum passage includes individually measuring the internal pressure of the plurality of vacuum passages using a plurality of pressure gauges respectively installed in the plurality of vacuum passages.

18. A substrate conveyance apparatus comprising:
a hand supporting a substrate, the hand having a plurality of holes formed in a surface thereof;
an adsorption unit including a plurality of vacuum pads, vacuum-adsorbing the substrate placed on the hand, and a vacuum passage;
a movement unit connected to one end of the hand, the movement unit moving the hand in a horizontal direction or a vertical direction;
a cooling plate cooling the substrate; and
a control unit controlling the hand, the adsorption unit, and the movement unit,
wherein the control unit determines, based on internal pressure of the vacuum passage, an adsorption state of the substrate, and controls, based on the adsorption state of the substrate, movement of the hand in the vertical direction.

19. The substrate conveyance apparatus of claim 18, wherein
the adsorption unit further includes a pressure gauge installed in the vacuum passage, the pressure gauge measuring internal pressure of the vacuum passage, and
the control unit determines the adsorption state of the substrate as an abnormal state when a measured value of the pressure gauge is less than a preset reference pressure value, and determines the adsorption state of the substrate as a normal state when the measured value of the pressure gauge is greater than the preset reference pressure value.

20. The substrate conveyance apparatus of claim 19, wherein the control unit determines the adsorption state of the substrate twice at a preset time interval, and places down the substrate from the hand onto the cooling plate, and lowers the hand to a position lower than the cooling plate using the movement unit, when the adsorption state of the substrate is determined as the abnormal state.
